(19) United States
(12) Patent Application Publication
(10) Pub. No.: US 2022/0231631 A1
(43) Pub. Date: Jul. 21, 2022

(54) FACADE ELEMENT AND PV MODULE FOR A FACADE ELEMENT

(71) Applicant: ASCA GmbH, Kitzingen (DE)

(72) Inventors: Bas Cedric Van Der Wiel, Nuernberg (DE); Marina Britvec, Nuernberg (DE); Pavel Schilinsky, Bremen (DE); Hafis Hermann Issa, Stuttgart (DE)

(21) Appl. No.: 17/717,476

(22) Filed: Apr. 11, 2022

Related U.S. Application Data
(63) Continuation of application No. PCT/EP2020/077667, filed on Oct. 2, 2020.

(30) Foreign Application Priority Data
Oct. 10, 2019 (DE) 10 2019 215 518.9

(51) Int. Cl. H02S 20/26; E06B 9/24; H02S 40/36; H02S 20/25; H02S 40/34

(52) U.S. Cl. CPC H02S 20/26; E06B 9/24; E06B 2009/2476; H02S 20/25; H02S 40/34; H02S 40/36

(57) ABSTRACT

A façade element has a plurality of photovoltaic (PV) modules, in particular organic PV modules, and a plurality of connectors. The PV modules are arranged flat so that each PV module is adjacent to one or more other PV modules. Each of the PV modules have two bus bars for the connection of one or more of the connectors, which bus bars are connected to one or more cells of the PV module. The bus bars of two adjacent PV modules are electrically connected to one another in parallel by a connector, so that the bus bars together with the connectors form an electrical grid.

### CROSS-REFERENCE TO RELATED APPLICATION

This application is a continuation, under 35 U.S.C. § 120, of copending International Patent Application PCT/EP2020/077667, filed Oct. 2, 2020, which designated the United States; this application also claims the priority, under 35 U.S.C. § 119, of German Patent Application DE 10 2019 215 518.9, filed Oct. 10, 2019; the prior applications are herewith incorporated by reference in their entirety.

### FIELD AND BACKGROUND OF THE INVENTION

The invention relates to a facade element and to a PV module for such a facade element.

A facade element is typically used to form a facade on a building and, on the finished building, accordingly constitutes part of its facade. The facade element is, for example, a wall element or a roofing element. A facade element may be installed both in the interior of a building and on the outside of the building.

PV modules, that is to say photovoltaic modules, are also referred to as solar cells and are used to convert light into electrical energy. A PV module generally has an active layer which is arranged between two electrodes. Light is absorbed in the active layer and a current is generated thereby, which current can be discharged via two connections. PV modules can be integrated in building facades in order to use the outer surface of the building to produce energy. In this case, the PV modules are fitted to individual facade elements which are then installed on the building.

Published, non-prosecuted German patent application DE 10 2017 214 347 A1 describes a facade element in which a plurality of PV modules is laminated between two panel elements. The PV modules are electrically connected to one another by means of respective contact elements. The PV modules may be connected in parallel or in series with one another or a combination thereof.

The specific connection of a plurality of PV modules to one another to form a PV system is subject to various boundary conditions. Such boundary conditions are, for example, electrical requirements with respect to the current and voltage of the PV system, installation space restrictions and design aspects. In this case, design aspects are particularly important since facade elements are typically visible and therefore should have a certain impression, that is to say optical appearance. The boundary conditions are also often different from building to building, with the result that the requirements sometimes change.

### SUMMARY OF THE INVENTION

Against this background, it is an object of the invention to make the arrangement of a plurality of PV modules of a facade element as simple and flexible as possible and to achieve a design of the facade element which is as appealing as possible. For this purpose, the intention is to specify a facade element and a PV module accordingly suitable for this.

The object is achieved, according to the invention, by means of a facade element having the features as claimed in the independent facade element claim and by means of a PV module having the features as claimed in the independent PV module claim. The subclaims relate to advantageous configurations, developments and variants. The statements made with respect to the facade element also analogously apply to the PV module and vice versa.

The facade element is used, in particular, to form a facade on a building and, in the installed state on the finished building, accordingly constitutes part of its facade. The facade element is, for example, a wall element or a roofing element. The facade element can be installed in the interior of a building or on the outside of the building.

The facade element has a plurality of PV modules, that is to say photovoltaic modules, for converting light into electrical energy. The facade element has at least two PV modules, but typically 10 to 100 PV modules. However, the number of PV modules is not restricted per se and is dependent on the intended use and the size of the facade element and, in particular, also on the respective size of the PV modules.

The PV modules are preferably organic PV modules, OPV modules for short, which are distinguished by a particular flexibility in terms of their design, on the one hand, and also by a particular mechanical flexibility, on the other hand. The shape of OPV modules and therefore their external impression can be designed particularly freely and can therefore be adapted to a specific application or user request. The design freedom also enables adaptation to particular electrical requirements with respect to the current and voltage of the PV module.

The PV modules are arranged flat, with the result that each PV module is adjacent to one or more other PV modules. In this case, the PV modules are usually arranged in a planar manner in a common plane. However, a flat arrangement, in which the PV modules are arranged flat along a bent, arched or curved surface or a surface of any other shape, is also possible and suitable.

In order to connect the PV modules to one another, the facade element has a plurality of connectors. In order to connect the connectors, a respective PV module has two busbars which are connected to one or more cells of the PV module. The cells are formed by an active layer connected to two electrodes. In order to form a plurality of cells, the active layer and the electrodes are structured accordingly. The cells are electrically connected to one another via suitable interconnects. The cells form, in particular, a cell array which additionally has at least two connection points which are used to connect the cells to the busbars. The busbars then each form a pole of the PV module for tapping off current, generally electrical energy, which is generated by the cells.

The busbars of two adjacent PV modules are electrically connected to one another by means of a respective connector and are connected in parallel with one another. For this purpose, a respective connector connects the two respective busbars of the PV modules to one another in pairs, with the result that two electrical connections are formed for the two poles. The busbars of two adjacent PV modules are electrically connected to one another by means of a respective connector and are connected in parallel with one another, with the result that the busbars form, with the connectors, a power supply system in which current is preferably conducted through adjacent PV modules in succession. This is understood as meaning the fact that the current is conducted through the busbars of adjacent PV modules in succession, but not necessarily through the cells of the PV modules. Therefore, there is preferably no electrical series connection of the cells of the PV modules, but rather the current is suitably conducted in turn, in particular alternately, through the connectors and the busbars to a respective PV module and is conducted from there through the cells of the various PV modules in a parallel manner. An individual connector is, in particular, electrically connected only to PV modules, that is to say not to other connectors, but rather an individual connector is connected to other connectors only indirectly via the busbars of the PV modules. A series connection of a plurality of PV modules is preferably dispensed with, and so a pure parallel circuit is implemented. The connectors connect, in particular, only PV modules directly adjacent to one another and are not used, in particular, to bridge or circumvent a PV module which is between two PV modules to be connected. A plurality of current paths is formed in the power supply system by alternately conducting the current through the busbars and the connectors. The flat arrangement means that the power supply system is also branched, that is to say the arrangement of the PV modules in two dimensions results in the formation of a plurality of current paths in different directions. A network or grid of PV modules is therefore implemented overall and therefore a power supply system in which a respective PV module is connected only to its directly adjacent PV modules. The current is not conducted, in particular, only along a simple chain of PV modules, but rather, as it were, in a two-dimensional manner through a power supply system in which the individual PV modules each form a linking point for a plurality of current paths. As a result, a respective PV module constitutes a distributor, also referred to as a “junction box”, for the current for distributing and forwarding the current to the adjacent PV modules. In particular, the specific geometry of the PV modules and especially of the busbars and of the cells is advantageously freely selectable to the greatest possible extent in order to implement such a distribution function.

All PV modules are connected to one another by the interaction of the busbars with the connectors. Accordingly, the connectors are particularly short and are typically considerably shorter than a respective PV module, since a respective connector bridges only the distance between the busbars of two adjacent PV modules. This avoids an accumulation of excessively long cables for connecting the PV modules in parallel. PV modules which are further away are connected only indirectly via the PV modules in between. The power supply system is therefore also decentralized, in particular, since each PV module distributes the current in the manner of a distributor or a junction box to the adjacent PV modules which in turn again distribute the current to adjacent PV modules in the same manner. Nevertheless, a parallel connection of all PV modules is formed overall. This results from the specific combination of the connectors with the busbars which together form the power supply system which is then a branched, bipolar power supply system. The facade element preferably has a central connection which is connected to the power supply system and therefore to the PV modules and is arranged centrally on the facade element, with the result that current paths which are as short as possible are implemented overall.

The invention is first of all based on the observation that a plurality of PV modules can fundamentally be connected in series or in parallel with one another or a combination thereof. Both series and parallel connections have specific advantages and disadvantages.

In a series circuit, a plurality of PV modules is connected in series in so-called strings (that is to say chains), with the result that the individual voltages of the PV modules are added. This is advantageous in large systems since high currents and corresponding electrical losses can be reduced. However, it is problematic that, if an individual PV module fails, the entire series circuit fails. Since the series circuit cannot be interrupted in any desired manner, the arrangement of the PV modules is not very flexible. In particular, it is difficult to form clearances between the PV modules in order to provide recesses for a window or a door in a facade element, for example. Furthermore, in a series circuit, it is not readily possible to combine PV modules of different sizes with one another, since all PV modules connected in series ideally provide the same current. In principle, it is possible to sort the PV modules according to size and to then join PV modules of the same size to form a respective string. It is also possible to design the PV modules of different sizes in such a manner that they produce the same current, but then also produce different voltages. A further problem is then the fact that the different strings ideally have the same voltage in order to be able to be connected in parallel with one another in an optimal manner. However, this is not necessarily the case and compliance with this condition considerably restricts the design freedom of the entire arrangement.

Conversely, it is possible to connect all PV modules in parallel with one another and, for this purpose, to design them in such a manner that all PV modules have the same voltage. A parallel circuit enables a considerably more flexible arrangement of the PV modules, but typically results in a high cabling outlay since a corresponding conductor must be run from each individual PV module to a central meeting point or to a common busbar. This impairs the design, especially the optical impression, of the arrangement, on the one hand, and makes it difficult to integrate the PV modules in a facade element, on the other hand. In addition, the voltage cannot be increased further, with the result that each individual PV module provides a voltage which is as high as possible in order to keep the electrical losses as low as possible, especially since the currents of the PV modules are added on account of the parallel circuit.

A core concept of the invention now involves, in particular, the special configuration and arrangement of the busbars of a respective PV module and their interaction with the connectors which electrically connect the busbars of adjacent PV modules and, in this manner, form a power supply system in which the PV modules are connected in parallel with one another and simultaneously act as distributors for the current. Various advantages result from this. First, the special connection means that the current is distributed from a respective PV module to adjacent PV modules and therefore results in a branched power supply system having advantageously redundant current paths, with the result that failure of an individual PV module is less problematic than in the case of a series connection, for example. Second, on account of the parallel circuit, it is possible to combine PV modules of different sizes with one another in any desired manner. PV modules of different sizes produce a different amount of current and are therefore not very suitable for a series circuit. Third, complicated cabling for producing the parallel circuit is avoided by keeping the connectors short and, in particular, connecting only adjacent PV modules to one another, with the result that the current is, as it were, passed through respectively adjacent PV modules in succession. Fourth, on account of the busbars, the PV modules can be assembled in indifferent and flexible ways, especially when PV modules of different sizes are combined with one another. Fifth, it is also possible to form gaps in the flat arrangement of the PV modules, thus resulting in a facade element with corresponding openings or recesses, for example for windows or doors or the like. The arrangement of the PV modules is therefore particularly flexible and enables particularly high design freedom when designing the facade element.

A respective connector connects the two busbars of a PV module to the two busbars of an adjacent PV module. A join which is possibly present between the PV modules is bridged in this case. However, further distances are not bridged, in particular, and a connector is therefore used only to connect directly adjacent PV modules. A connector therefore has a length which is at least less than the width of a PV module and is preferably only a few centimeters, for example 1 cm to 5 cm. Depending on the spacing and arrangement of the PV modules, however, longer connectors are also conceivable and suitable, for example for bridging larger distances between two adjacent PV modules. A respective connector has a bipolar design and therefore has two conductors, one for each of the two polarities of the busbars. The connector either has a one-part design, that is to say both conductors are combined, or a multi-part design, with the result that the two connections are independent of one another. In the simplest case, a connector has two cables or two metal strips or metal rails.

In principle, it is sufficient if two adjacent PV modules are connected via a single connector. However, a configuration in which two adjacent PV modules are connected several times, that is to say redundantly, by means of a plurality of connectors is also suitable. As a result, further current paths are produced and the power supply system is branched further. In particular, the effective resistance also falls as a result on the way from a PV module to a central connection. In one suitable configuration, the busbars have a poorer conductivity than the connectors due to production, with the result that additional connectors are accordingly advantageous. The mechanical coupling of the PV modules is also more robust, which is particularly advantageous when producing the facade element if the PV modules are not yet held by a common carrier layer.

The two busbars of a PV module are each preferably in the form of elongated conductor tracks or in the form of a conductor track network having a plurality of elongated sections. In one preferred configuration, the two busbars of a respective PV module run beside one another, that is to say in two tracks as twin conductors. In this case, the two busbars preferably also run parallel to one another. The two busbars do not necessarily follow a straight course, but rather are preferably kinked or bent in order to follow the corresponding edge region. However, a straight course is also suitable depending on the application. An accordingly short distance is formed between the two busbars and, in one suitable configuration, is in the range of 0.5 mm to 2 mm and is typically 1 mm. The distance results, in particular, from a registration error when producing the PV module and forming the two busbars. The busbars are initially connected, in particular, and are then separated from one another by means of a laser. The distance between the busbars is then twice the registration error. Both busbars are preferably completely covered by the active layer.

A configuration in which the busbars run beside one another and along an edge region of the PV module, with the result that one of the two busbars is an inner busbar and the other of the two busbars is an outer busbar, is particularly preferred. In this case, the busbars do not necessarily run along the entire edge region, but expediently along a plurality of sides of the PV module, with the result that the latter can be connected to other PV modules in different directions. In this way, the PV modules can be connected in a particularly flexible manner and the facade element has a high degree of design freedom. Instead of routing the busbars along opposite sides of the cells of a semiconductor module, as in published, non-prosecuted German patent application DE 10 2017 214 347 A1 mentioned at the outset, both busbars are routed beside one another in the present case, that is to say as edge conductors.

In the configuration with busbars in the edge region, a respective PV module is subdivided into an inner region and an edge region. The cells are arranged, in particular, only in the inner region and do not extend into the edge region. The edge region outwardly forms an outer edge of the PV module. Inwardly, the edge region adjoins the inner region and surrounds the latter. The two busbars are, in particular, arranged completely in the edge region and therefore between the outer edge, on the one hand, and the cells, on the other hand. The outer busbar runs between the outer edge and the inner busbar, and the inner busbar accordingly runs between the outer busbar and the cells. The active layer is, in particular, not restricted to the inner region, but rather expediently extends into the edge region, for the esthetic and optically consistent design of the PV module, and then possibly overlaps the busbars.

In one preferred configuration, at least one of the busbars, preferably both busbars, in a respective PV module is/are in the form of a closed conductor loop. The busbar then completely runs around the inner region and the cells and encloses them. This configuration is particularly flexible in terms of the possible connections since the PV module now enables a connection on all sides. The busbar in this case expediently follows the outer contour of the PV module, with the result that, in the case of a square PV module, the busbar accordingly has a square course, possibly with rounded corners, or even circular. If both busbars are in the form of a conductor loop, they preferably run in a concentric manner. Both busbars of a PV module are each electrically connected to the cells via at least one connection point. A busbar which is in the form of a conductor loop has the special advantage that the current path from a connector to the cells always corresponds at most to half a revolution around the cells. This is because, starting from the connector, there are always two possible current paths to the connection point, of which the current follows that one with the lowest resistance, with the result that electrical losses are minimized. In contrast, in an interrupted busbar, the current path is unambiguously predefined.

Since the two busbars of a respective PV module run beside one another, the inner busbar is basically in the way of the outer busbar when making contact with the cells. There are various possibilities for establishing contact between the outer busbar and the cells in the inner region. Some suitable configurations are mentioned below.

In one suitable configuration, in a respective PV module, the inner busbar is interrupted by the outer busbar in order to make contact with the cells. The inner busbar is therefore not in the form of a closed conductor loop, but rather suitably has two arms which, starting from the connection point for the cells, extend around the latter to a feed-through for the outer busbar. The inner busbar is preferably interrupted only locally and is therefore in the form of an interrupted conductor loop which completely surrounds the cells, with the exception of the feed-through. In order to make contact with the cells, the outer busbar has a branch which runs through the feed-through to the inner region and is connected there to the cells. This configuration is particularly simple, in particular in terms of production, but has the disadvantage that the inner busbar is interrupted. This disadvantage is preferably compensated for by interrupting the inner busbar on that side of the PV module which is opposite the connection point at which the inner busbar is connected to the cells. As a result, both arms of the inner busbar have the same or at least a similar length.

In another suitable configuration, in a respective PV module, the outer busbar is connected to the cells by means of a bridge which bridges the inner busbar. The inner busbar then need not be interrupted, but rather is advantageously in the form of a closed conductor loop. In one particularly simple configuration, the bridge is a simple conductor element, for example similar to the above-described branch of the outer busbar when the inner busbar is interrupted, with the difference that the branch is now routed through over the inner busbar or below the latter. In this case, an insulating material is expediently arranged between the branch and the inner busbar in order to prevent a short circuit.

In one advantageous variant, the bridge is formed by one of the connectors which connects the outer busbar, which is on the outside of the inner busbar, to a contact section, which is on the inside of the inner busbar, that is to say on the opposite side. A contact section which is connected to the cells is therefore arranged on that side of the inner busbar which is opposite the outer busbar. In one configuration, the contact section corresponds to the connection point to the cells, and, in another configuration, the contact section is a separate conductor which leads to the connection point and in this case preferably runs beside the inner busbar. This configuration has the advantage that there is no need for multi-layer production of the outer busbar in order to route the current path for bridging the inner busbar out of the plane thereof. Rather, the connector which is present anyway is simply used as a bridge.

In one advantageous variant, the bridge has a diode for stipulating the current direction through the cells. This avoids negative effects in the event of failure of the PV module or shading. The arrangement of a diode along a busbar itself is not readily possible since, depending on the connection, the current flows through the busbar in one direction or the other. However, the current should always flow in the same direction along the bridge, with the result that the arrangement of a diode is advantageous here. In principle, a configuration in which the diode is part of a connector and is connected there between the outer busbar and the contact section is also possible and suitable.

As an alternative to the above-described configuration of a PV module in which the two busbars are arranged as an inner and an outer busbar in an edge region, other arrangements of the busbars are also conceivable and suitable. The busbars do not necessarily run in the edge region, but rather run through the PV module in a suitable variant and thereby subdivide the cell array into a plurality of cell sectors which are not directly connected to one another, but rather are only indirectly connected via the busbars. In one advantageous configuration, the two busbars run beside one another and each run in a cruciform manner through a center of the PV module. In this case, the two busbars bridge one another. Accordingly, the cell array is subdivided into four cell sectors, that is to say quadrants. Each cell sector is connected to the two busbars, preferably in such a manner that all cells of a respective cell sector are connected in series with one another.

It emerges from the previous statements that the course of the two busbars and their arrangement along the PV module can fundamentally be freely selected, wherein some configurations, for example the configurations which have already been mentioned, have special advantages. In any case, the busbars preferably run at least partially in an edge region of the PV module, with the result that the busbars are laterally accessible for the connectors in a particularly simple manner. Therefore, the connectors are preferably connected in the edge region. For example, a respective PV module has a polygonal design and has an outer edge with a plurality of sides. Each busbar then preferably has a connection point for a respective connector on each side. In the case of a square PV module, there are therefore at least eight connection points, specifically at least two for each side and at least four for each busbar. Depending on the size of the PV module, a plurality of connection points for each busbar and each side are advantageous.

A respective PV module has two conductive layers as electrodes which are encapsulated together with an active layer between two barrier layers. The active layer and the two electrodes are not necessarily each individual layers, but are typically themselves composed of a plurality of layers. The active layer has a semiconductor material for producing charge carriers which then migrate to the electrodes and result in a corresponding current. The entire layer structure comprising the active layer and electrodes is encapsulated between two barrier layers for protection against environmental influences. The barrier layers form an outer sheath of the PV module. The active layer and the electrodes are preferably laminated between the barrier layers. The barrier layers are then also referred to as a primary laminate. The barrier layers are preferably composed of a transparent plastic, for example PET. The barrier layers form, in particular, a completely circumferential packing edge, with the result that the PV module is also closed on the sides.

The barrier layers determine a total area of the PV module, and the active layer forms a partial area of the total area. The barrier layers are typically transparent, whereas the active layer absorbs at least some incident light and, as a result, optically stands out from regions without an active layer. This forms two regions, specifically an absorbing region, which corresponds to the partial area, that is to say the active layer, and a transparent region, in particular the packing edge, which corresponds to the difference between the total area and the partial area and surrounds the absorbing region, in particular completely.

In one particularly preferred configuration, the two busbars are also arranged between the two barrier layers of a respective PV module, with the result that they are integrated in the PV module. This considerably simplifies the production of the PV module and accordingly also the production of the facade element. Instead of subsequently fitting the busbars as separate components to the PV module, they are already integrated in the PV module during production.

The busbars of a respective PV module are preferably produced together with one of the electrodes, specifically by printing on a conductive material. This configuration is based on the consideration that suitable busbars can also be produced from that material which is used to produce the electrode. One of the electrodes, in particular the so-called top electrode, is suitably printed on as a so-called grid electrode. A conductive ink containing conductive particles, for example silver, is used as conductive material for this purpose. The busbars are now also printed on in the same process step as the electrode, that is to say they are also in the same layer as the electrode in the layer structure of the PV module. The production of the busbars is thereby particularly simple since there is no additional process step. Additional metal strips or even cables are expediently dispensed with.

Within the scope of the concept of a PV module as a distributor, all busbars and possibly all additional conductors for connecting the cells to the busbars are advantageously integrated in the PV module, with the result that a respective PV module constitutes, as it were, a complete and self-contained module which is easily connected to other PV modules only by means of connectors when producing the facade element. An individual PV module then constitutes an overall self-contained and functional very small structural unit. All cells, busbars, connection points and contact points of an individual PV module are electrically connected inside this module, in particular, for this purpose. External conductors, that is to say, in particular, conductors outside the barrier layers, for connecting different parts of an individual PV module are preferably dispensed with. External conductors are preferably used at most in the already described form as part of a connector.

A conductor which has been printed on, that is to say also a busbar which has been printed on, typically has, on account of the production method, a poorer conductivity than a solid conductor which is subsequently adhesively bonded, for example as a metal strip, even for the same dimensions. However, it was observed in the present case that this disadvantage is compensated for by the branched power supply system and the multiplicity of possible current paths inside the facade element, and a reasonable loss on account of the electrical resistance of the busbars is produced. It was thus determined in simulations that the electrical loss caused by busbars which have been printed on is only 5% to 10%.

If the busbars are integrated in a respective PV module, the busbars are covered by the barrier layers. In one expedient configuration for establishing contact between a connector and a PV module, its one barrier layer has a contact hole through which one of the busbars is accessible. A respective contact hole therefore exposes a connection point for a connector on a busbar. The contact hole is cut into the barrier layer, for example by means of a laser, for example when producing the PV module. This can be readily integrated in the production method and is preferably also integrated, especially since the barrier layers are often also finally trimmed with a laser anyway. The contact hole is circular, for example, with a diameter corresponding to a maximum width of the busbar. A respective busbar preferably has a width of between 1 mm and 3 mm, for example 2 mm. Since two busbars are present in each PV module, at least two contact holes are accordingly present, specifically one for each busbar. In order to make it possible to flexibly establish contact on different sides of the PV module, however, a plurality of contact holes are preferably formed for each busbar, expediently at least one contact hole on each side of the PV module. In one advantageous configuration, the contact holes are arranged centrally in the edge region of a respective PV module, wherein the two contact holes for the different poles are offset relative to one another. In principle, however, other arrangements of the contact holes are also conceivable and suitable, depending on the design of the PV modules. A configuration in which an individual contact hole is in the form of a slot, for example, and extends over both busbars, with the result that an individual contact hole exposes two connection points, is also fundamentally conceivable and suitable.

As an alternative to forming contact holes, a respective connector is advantageously designed in such a manner that, during connection to a PV module, it pierces its one barrier layer in the region of one of the two busbars in order to make contact with the latter. For this purpose, the connector is in the form of a crimp, for example, and has one or more teeth or mandrels which perforate the barrier layer when being pressed onto the PV module and then establish electrical contact with the busbar underneath. This configuration has the advantage that the position of the connector is not predetermined by the production of the PV module, but rather is subsequently freely selectable when assembling a plurality of PV modules.

The configuration with the connector which pierces the barrier layer in order to make contact can fundamentally also be combined with a PV module having contact holes, with the result that certain positions for the connectors, especially connectors without teeth or mandrels, are prepared and predefined, on the one hand, and special connectors for making contact away from these positions can also be used, on the other hand.

In principle, it is possible for a respective PV module to have only a single cell. The resulting voltage is then accordingly low, however, and so a respective PV module preferably has a plurality of cells which are connected in series with one another, thus resulting in a correspondingly high voltage.

A particularly simple form for the cells is a strip form, with the result that all cells of a PV module are then in the form of strips and are arranged beside one another in a parallel manner, with the result that a current path from one side of the cells to the other is produced. Two adjacent cells are each connected by means of an interconnect in order to implement a series circuit. Depending on the size of the PV module and depending on the desired voltage, however, very narrow strips and a very large amount of dead space on account of the interconnects possibly arise. In order to avoid this, there is expediently a departure from the strip form.

In one particularly advantageous configuration, all cells of a respective PV module are connected in series with one another in such a manner that a meandering current path is formed. The cells are therefore not arranged beside one another in the form of strips, but rather are arranged in a matrix-like manner, specifically in a two-dimensional cell array. This forms a plurality of columns in which the cells are each connected in series. The columns are then connected to one another at their ends, thus accordingly resulting in a meandering connection in which all cells are connected in series. This minimizes the dead space and increases the area which can be used to generate energy. The statements similarly apply to PV modules having a plurality of cell sectors, with the result that all cells in each cell sector are then connected in series with one another, preferably in a meandering manner. However, the different cell sectors are connected in parallel with one another.

A suitable voltage is achieved, in particular, in a respective PV module by connecting 50 to 100 cells in series. A voltage in the range of 25 V to 120 V is therefore preferably produced. Depending on the application, however, different numbers of cells are also suitable. Irrespective of the number of cells, all cells of a PV module are preferably of the same size, with the result that all cells produce the same current, which is advantageous in a series circuit. Depending on the dimensions of the PV module, the size of an individual cell is possibly very small, but this is not disadvantageous since, on account of the parallel circuit of a plurality of PV modules, their currents are added. In one suitable configuration, an individual cell has a size in the range of 0.3 cm² to 4 cm², depending on the size of the PV module. The size of the cells is expediently selected in such a manner that a voltage which is as high as possible is produced. The size of a respective PV module is, for example, in the range of 40 cm² to 400 cm² or even up to 1400 cm². In particular, the size of an individual cell scales with the size of the PV module and is proportional thereto. This is the case, in particular, with PV modules of different sizes for a stipulated system voltage of the facade element.

A particular advantage of the special design of the busbars and of the connection which is particularly flexible as a result is that PV modules of different sizes can be combined with one another. Accordingly, in one particularly preferred configuration, the facade element has a plurality of different types of PV modules of different sizes. The different types therefore differ in terms of their size, that is to say the physical dimensions. In particular, at least two types differ to the effect that they have different areas, with the result that the size of the cells also accordingly differs and the PV modules produce different currents. However, as described, the number of cells is preferably the same, with the result that the different types have the same voltage and can be connected in parallel with one another without any problems.

In one particularly advantageous configuration, a plurality of types of PV modules differ in terms of their size and are adapted in this case to a grid dimension which has a particular size as the base unit, and the sizes of the various types are each integer multiples of this base unit. The base unit therefore represents, as it were, an individual pixel in the overall flat arrangement of the PV modules as a multiplicity of pixels, wherein each PV module corresponds to one or more pixels. If appropriate, slight deductions or additions are made with respect to the size in order to enable additional joins between adjacent PV modules. In one preferred configuration, the connectors follow the grid dimension, with the result that the connectors are arranged in a manner distributed at regular intervals over the entire flat arrangement of the PV modules, and accordingly large PV modules are then possibly connected several times to an accordingly large, adjacent PV module via a plurality of connectors.

The PV modules preferably each have a polygonal design and are arranged in a tile-like manner. In one suitable configuration, the PV modules are each square and accordingly have four corners. A rectangular grid dimension, along which the PV modules can be positioned, accordingly results, in particular. Particularly expedient is a configuration in which the grid dimension has a square as a base unit, with the result that the PV modules are then accordingly rectangles or even squares, the area of which corresponds to an integer multiple of the base unit. In this manner, the PV modules can be arranged in an optically attractive manner in the form of a brick wall or a backsplash, which is also the case in one preferred configuration.

The optical impression of a respective PV module is advantageously produced by appropriately designing the individual elements of a respective PV module, thus also resulting overall in a particular design for the facade element. In one advantageous configuration, the active layer of a respective PV module is designed for this purpose in such a manner that an irregular contour results, for example a brick finish. This is based on the consideration that the barrier layers are usually transparent, but the active layer and the busbars are not, with the result that the optical impression of an individual PV module and of the facade element is overall decisively determined by the form of the active layer. The busbars are also suitable for the optical design. Therefore, the active layer or the busbars or both is/are preferably used for the design. For example, the busbars follow a course reproducing a corresponding contour of the active layer, with the result that the active layer is framed, as it were, by the busbars. A non-uniform, spiral course is particularly suitable, thus resulting in a brick finish in which the active layer and the busbars then represent a brick and the spacing between adjacent PV modules which is produced by the barrier layers represents the corresponding mortar between the bricks. If the busbars are completely covered by the active layer, the busbars are typically visible only from one side, preferably a rear side, which is not visible when the facade element is installed as intended, but rather faces an installation surface, with the result that only a front side is visible, the impression of which is decisively made by the active layer.

The facade element itself is expediently a laminate, in which the PV modules are laminated together between two layers. In one suitable configuration, the PV modules are enclosed together between a front side and a rear side of a secondary laminate. The front side and the rear side therefore form two layers of a laminate and the PV modules are fastened in between, in particular. The front side and/or the rear side is/are expediently produced from a transparent material. Configurations in which the front side and the rear side have different transparencies, for example the rear side is opaque or non-transparent, are also expedient. Suitable materials for the front side and the rear side are glass and polycarbonate (PC). The front side and the rear side are preferably connected to the PV modules by means of an adhesive and, as a result, are fixed and fastened to one another. The adhesive is, for example, a so-called “hot melt” which is applied for lamination between the front side and the rear side.

The connectors are preferably also enclosed together with the PV modules between the front side and the rear side when producing the facade element and, as a result of this, are accordingly arranged inside the secondary laminate and are generally integrated in the facade element.

In the case of the flat arrangement of the PV modules, a plurality of recesses, which the adhesive can enter, are expediently formed between the PV modules, with the result that this adhesive extends through the area of the PV modules and directly connects the front side to the rear side. Such recesses may be realized in different ways.

In one expedient configuration, the PV modules are spaced apart from one another by means of joints in which the adhesive connecting the front side to the rear side is arranged. The joints are similar to those joints which are formed when laying tiles or building a wall. The joints have a joint width which is considerably smaller than the width of a PV module and, in particular, is also considerably narrower than the grid dimension. In one suitable configuration, the joint width is 5 mm to 20 mm.

As an alternative or in addition to the joints, in a configuration which is likewise suitable, a respective PV module has a contoured outer edge, with the result that adjacent PV modules abut one another only in sections and in this case form one or more recesses in which an adhesive connecting the front side to the rear side is arranged. This shall be explained, by way of example, on the basis of rectangular PV modules, but is also analogously applied to PV modules of other shapes: a rectangular PV module has a generally rectangular outer edge which is now recessed in sections, with the result that additional steps or notches are formed along the outer edge. Two PV modules whose outer edges are placed onto one another then abut one another, but not in the region of the steps or notches which form corresponding recesses by virtue of the interaction of the two outer edges of the adjacent PV modules. The recesses are generally preferably produced by additionally processing the barrier layers of a respective PV module, wherein one or more recesses are cut out or stamped in. The recesses are formed, in particular, only in the edge region and therefore do not influence the inner region, the cells and the active layer. In one suitable configuration, the recesses are rectangular or in the form of strips, but many other forms are fundamentally likewise suitable. A PV module preferably has a plurality of recesses which are expediently arranged on different sides of the PV module, with the result that the PV module is surrounded or framed by adhesive from a plurality of sides in the finished facade element.

Alternatively or additionally, the recesses are in the form of holes in a respective PV module, preferably in its edge region. In a similar manner to the recesses in the case of a contoured outer edge, the holes pierce the entire PV module, especially the two barrier layers, and in this manner make it possible for the adhesive to penetrate from one side to the other. Unlike in the case of the contoured outer edge, however, the holes are completely bordered by the barrier layers of an individual PV module and not by the outer edges of two adjacent PV modules. Like in the case of the contoured outer edge as well, it is advantageously possible in a configuration with holes to arrange the PV modules end-to-end and to avoid a joint, thus considerably simplifying the assembly and production of the facade element since no joint dimension needs to be taken into account. In addition, in the case of an end-to-end arrangement, the mechanical load on the connectors is also relieved since the PV modules are additionally mechanically connected directly on their outer edges.

A configuration in which a respective PV module has an outer edge contoured in such a manner that an orientation relative to adjacent PV modules is restricted and polarity reversal protection is thus formed is also expedient. This is particularly advantageous when special contact holes for connecting the connectors are present. However, depending on the course of the busbars, it is also generally possible for the specification of a particular orientation to be advantageous in order to avoid having to use differently shaped connectors and to ensure overall that contact is made with the PV modules correctly. Two complementary structures, for example a projection and a complementary recess, for example a tip and an indentation on opposite sides of a respective PV module, are suitably formed on the outer edge. An outer edge contoured in this manner is used to establish the orientation of the PV modules relative to one another, in a similar manner to puzzle pieces.

The object is also achieved, in particular, by means of a construction kit for a facade element as described above. The construction kit has a plurality of PV modules and connectors as described which can be assembled in various arrangements and then, in an installed state, produce a facade element. The object is also respectively achieved, in particular, by means of a method for producing a PV module or a facade element, wherein method steps for respective production emerge from the previous statements.

Other features which are considered as characteristic for the invention are set forth in the appended claims.

Although the invention is illustrated and described herein as embodied in a facade element and a PV module for a facade element, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, top view of a facade element;

FIG. 2 is a top view of a section of the facade element from FIG. 1;

FIG. 3 is a top view of two PV modules and one connector;

FIG. 4 is a sectional view of a PV module;

FIG. 5 is a top view of one variant of the PV module;

FIG. 6 is a top view of a further variant of the PV module;

FIG. 7 is an illustration of a section of one variant of the facade element from FIG. 1;

FIG. 8 is a side view of sections of a connector;

FIG. 9 is a top view of a further variant of a PV module;

FIG. 10 are illustrations of four variants of PV modules of different sizes;

FIG. 11 is a sectional view of one variant of the facade element; and

FIG. 12 is a top view of a further variant of a PV module.

### DETAILED DESCRIPTION OF THE INVENTION

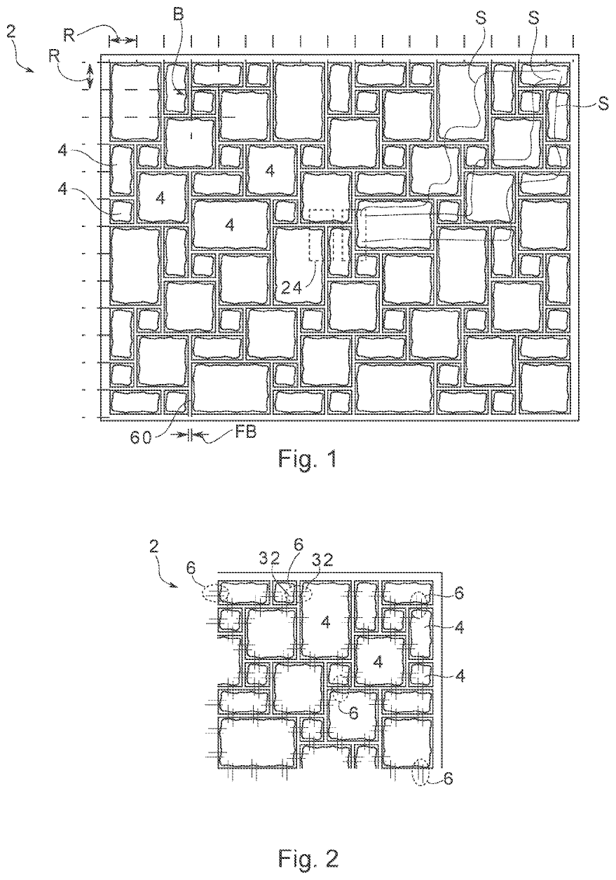

Referring now to the figures of the drawings in detail and first, particularly to FIG. 1 thereof, there is shown an exemplary facade element 2. It is used to form a facade on a building which is not illustrated in any more detail. The facade element 2 has a plurality of PV modules 4, that is to say photovoltaic modules, for converting light into electrical energy. The number of PV modules 4 is dependent on the intended use and the size of the facade element 2. In the exemplary embodiment shown, the PV modules 4 are organic PV modules, OPV modules for short, which are distinguished by a particular flexibility in terms of their design, on the one hand, and also by a particular mechanical flexibility, on the other hand. As a result, the shape of the PV modules 4 and therefore their outer impression can be freely designed and adapted.

As becomes clear from FIG. 1, the PV modules 4 are arranged flat, with the result that each PV module 4 is adjacent to one or more other PV modules 4. In the exemplary embodiment shown, the PV modules 4 are arranged in a planar manner in a common plane. In a variant which is not shown, the PV modules 4 are arranged flat along a bent, arched or curved surface or a surface of any other shape.

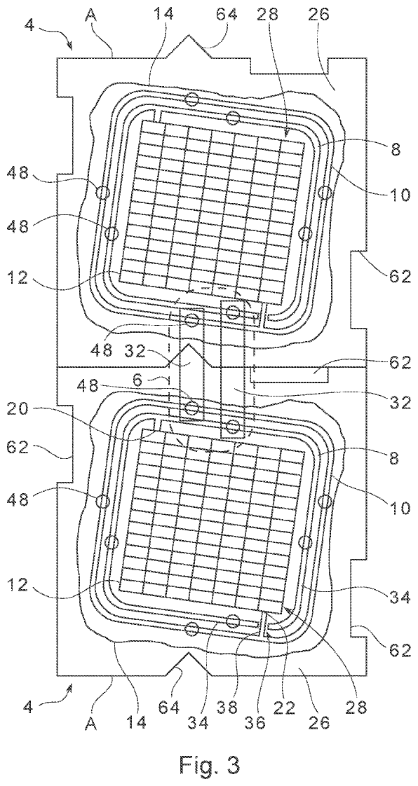

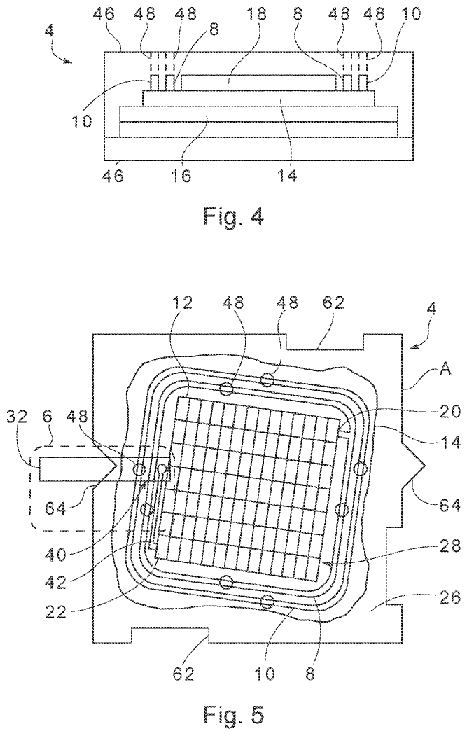

In order to connect the PV modules 4 to one another, the facade element 2 has one or more connectors 6 which can be seen in FIGS. 2 and 3, but are not explicitly shown in FIG. 1. FIG. 2 shows a section from FIG. 1, and FIG. 3 shows two PV modules 4 which are connected by means of a connector 6. It can clearly be seen in FIG. 3 that a respective PV module 4 has, for connecting the connectors 6, two busbars 8, 10 which are connected to one or more cells 12 of the PV module 4. The cells 12 are formed by an active layer 14 connected to two electrodes 16, 18. This structure of an individual PV module 4 can be seen in FIG. 4 which shows a sectional view of a PV module 4. In order to form a plurality of cells 12, the active layer 14 and the electrodes 16, 18 are structured accordingly. The electrode 16 is applied to a substrate which is not explicitly described, for example made of PET, and extends to the outer edge A of the PV module 4 in the present case. The cells 12 are electrically connected to one another via interconnects, which are not explicitly illustrated, and form a cell array which additionally has at least two connection points 20, 22 which are used to connect the cells 12 to the busbars 8, 10. The busbars 8, 10 then each form a pole of the PV module 4 for tapping off the electrical energy which is generated by the cells 12.

As can be seen from FIGS. 2 and 3, two adjacent PV modules 4 each are electrically connected to one another by means of a respective connector 6 and are connected in parallel with one another. For this purpose, a respective connector 6 connects the two respective busbars 8, 10 of the PV modules 4 to one another in pairs, thus forming two electrical connections for the two poles. A series connection of PV modules 4 is entirely dispensed with here, with the result that a pure parallel circuit is implemented. A power supply system is implemented overall, in other words: a network or grid of PV modules 4, in which a respective PV module 4 is connected only to its directly adjacent PV modules 4. The connectors 6 are accordingly short and, as shown, are considerably shorter than a respective PV module 4. PV modules 4 which are further away are connected only indirectly via the PV modules 4 in between. The busbars 8, 10 form, with the connectors 6, a power supply system in which current is conducted through adjacent PV modules 4 in succession. An individual connector 6 is electrically connected only to PV modules 4, that is to say not to other connectors 6, but rather an individual connector 6 is connected to other connectors 6 only indirectly via the busbars 8, 10 of the PV modules 4. Nevertheless, a parallel circuit of all PV modules 4 is formed overall. This results from the special combination of the connectors 6 with the busbars 8, 10 which together form a branched, decentralized, bipolar power supply system. In the power supply system, a plurality of current paths S are formed by conducting the current alternately through the busbars 8, 10 and the connectors 6. As a result of the flat arrangement, the power supply system is also branched, that is to say the arrangement of the PV modules 4 in two dimensions results in a plurality of current paths S being formed in different directions. Three exemplary current paths S between two of the PV modules 4 are explicitly depicted in FIG. 1. Corresponding current paths S result between any two of the PV modules 4. The facade element 2 shown here additionally also has a central connection 24 which is connected to the power supply system and therefore to the PV modules 4 and is arranged centrally on the facade element 2 here, thus resulting in current paths S which are particularly short overall.

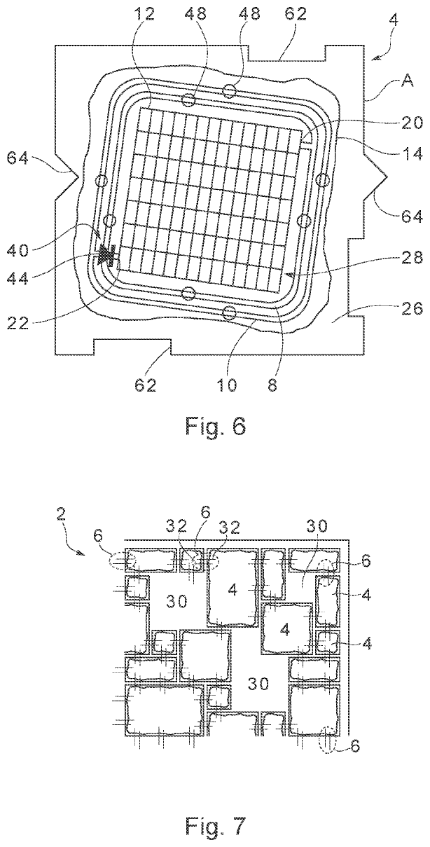

In addition to the exemplary embodiment of a PV module 4 shown in FIG. 3, FIGS. 5 and 6 show further exemplary embodiments of a PV module 4. In each of these cases, the two busbars 8, 10 of a PV module 4 are each in the form of elongated conductor tracks 8, 10. The two busbars 8, 10 of a respective PV module 4 run beside one another, that is to say in two tracks as twin conductors, along an edge region 26 of the PV module 4, with the result that one of the two busbars 8, 10 is an inner busbar 8 and the other of the two busbars 8, 10 is an outer busbar 10. In FIGS. 3, 5 and 6, the busbars 8, 10 run along the entire edge region 26, but this is not necessarily always the case, as shown by the exemplary embodiment in FIG. 12. However, in FIGS. 3, 5 and 6, the busbars 8, 10 run along a plurality of sides of the PV module 4, with the result that the latter can be connected to other PV modules 4 in different directions, here four directions, as also becomes clear from FIG. 2. In this manner, the PV modules 4 can be flexibly connected and the facade element 2 has a high degree of design freedom. Instead of routing the busbars 8, 10 along opposite sides of the cells 12, both busbars 8, 10 are routed beside one another in the present case, that is to say as edge conductors. In the exemplary embodiments shown, the two busbars 8, 10 even run parallel to one another. In addition, the two busbars 8, 10 do not follow a straight course, but rather are kinked or bent in order to follow the correspondingly running active layer 14.

A respective PV module 4 is subdivided into an inner region 28 and an edge region 26. The cells 12 are arranged only in the inner region 28 and do not extend into the edge region 28. The edge region 28 outwardly forms an outer edge A of the PV module 4. The edge region 26 inwardly adjoins the inner region 28 and surrounds the latter. The two busbars 8, 10 are arranged completely in the edge region 26 and therefore between the outer edge A, on the one hand, and the cells 12, on the other hand. The outer busbar 10 runs between the outer edge A and the inner busbar 8, and the inner busbar 8 accordingly runs between the outer busbar 10 and the cells 12. The active layer 16 is not restricted to the inner region 28, but rather extends in the present case into the edge region 26 for the esthetic design of the PV module 4 and overlaps the busbars 8, 10.

As is especially clear from FIGS. 2 and 3, the busbars 8, 10 of a respective PV module 4 and the connectors 6, which electrically connect the busbars 8, 10 of adjacent PV modules 4, interact in such a manner that a network, in which the PV modules 4 are connected in parallel with one another, is formed. Therefore, the result is a branched power supply system with redundant current paths S, some of which are depicted by way of example in FIG. 1. A respective PV module 4 therefore acts as a distributor, also referred to as a “junction box”, and enables various current paths S.

It also becomes clear from FIGS. 1 and 2 that, on account of the parallel circuit, PV modules 4 of different sizes can be combined with one another in any desired manner. PV modules 4 of different sizes produce a different amount of current and are therefore not very suitable for a series circuit. Complicated cabling for producing the parallel circuit is avoided by keeping the connectors 6 short and connecting only adjacent PV modules 4 to one another. On account of the busbars 8, 10 running beside one another in the edge region 26, the PV modules 4 can be assembled in different and flexible ways, especially when PV modules 4 of different sizes are combined with one another, as in FIGS. 2 and 3. FIG. 7 shows a section of one variant of the facade element 7, in which gaps 30 are formed in the flat arrangement of the PV modules 4, thus resulting in a facade element 2 having corresponding openings or recesses, for example for windows or doors or the like, which is especially possible on account of the parallel circuit.

As can be seen, in particular, in FIG. 3 but also in FIG. 2, a respective connector 6 has a bipolar design and therefore has two conductors 32, one for each of the two polarities of the busbars 8, 10. The connector 6 either has a one-part design, that is to say both conductors 32 are combined, or a multi-part design, with the result that the two connections are independent of one another. In principle, it is sufficient if two adjacent PV modules 4 are connected via a single connector 6. However, also suitable is a configuration in which two adjacent PV modules 4 are connected several times, that is to say redundantly, by means of a plurality of connectors 6, as is the case in FIGS. 2 and 7 for some of the larger PV modules 4. This produces further current paths S. The mechanical coupling of the PV modules 4 is also more robust.

In the PV modules 4 in FIGS. 3, 5 and 6, at least one of the busbars 8, 10 is in the form of a closed conductor loop. In FIGS. 5 and 6, both busbars 8, 10 are even each in the form of a closed conductor loop. The busbar 8, 10 in the form of a closed conductor loop completely runs around and encloses the inner region 28 and the cells 12. As a result, the PV module 4 enables a connection on all sides. In this case, the busbar 8, 10 follows the outer contour A of the PV module 4, with the result that, in the case of the square PV modules 4 shown, the busbar 8, 10 accordingly has a square course, here with rounded corners. In contrast, in FIG. 12, the busbars 8, 10 run through the PV module 4 and, as a result, subdivide the cell array into a plurality of, here four, cell sectors 66 which are not connected to one another directly, but rather only indirectly via the busbars 8, 10. In FIG. 12, the two busbars 8, 10 run beside one another and each in a cruciform manner through a center of the PV module 4 and bridge one another in this case. Each cell sector 66 is connected to the two busbars 8, 10, in the present case in such a manner that all cells 12 of a respective cell sector 66 are connected in series with one another.

Both busbars 8, 10 of a PV module 4 are each electrically connected to the cells 12 via at least one connection point 20, 22. A busbar 8, 10 which is in the form of a conductor loop has the special advantage that the current path S from a connector 6 to the cells 12 always corresponds at most to half a revolution around the cells 12. This is because, starting from the connector, there are always two possible current paths S to the connection point 20, 22, of which the current follows that path with the lowest resistance. In contrast, in the case of an interrupted busbar 8, 10, as in FIG. 3, the current path S is unambiguously predefined.

Since the two busbars 8, 10 of a respective PV module 4 run beside one another, the inner busbar 8 in FIGS. 3, 5 and 6 is basically in the way of the outer busbar 10 when making contact with the cells 12. There are various possibilities for establishing contact between the outer busbar 10 and the cells 12 in the inner region 28. Three suitable configurations are shown in FIGS. 3, 5 and 6 and are described in more detail below.

In the PV modules 4 in FIG. 3, the inner busbar 8 is interrupted by the outer busbar 10 in order to make contact with the cells 12. The inner busbar 8 is therefore not in the form of a closed conductor loop, but rather has two arms 34 which, starting from the connection point 20 for the cells 12, extend around the latter as far as a feed-through 36 for the outer busbar 10. In the exemplary embodiment shown, the inner busbar 8 is interrupted only locally and therefore is in the form of an interrupted conductor loop which completely surrounds the cells 12, with the exception of the feed-through 36. In order to make contact with the cells 12, the outer busbar 10 has a branch 38 which runs through the feed-through 36 to the inner region 28 and is connected to the cells 12 there. In the present case, the inner busbar 8 is specifically interrupted on that side of the PV module 4 which is opposite the connection point 20 at which the inner busbar 8 is connected to the cells 12. As a result, both arms 34 of the inner busbar 8 have the same or at least a similar length.

In contrast, in the exemplary embodiments in FIGS. 5 and 6, in a respective PV module 4, the outer busbar 10 is connected to the cells 12 by means of a bridge 40 which bridges the inner busbar 8. The inner busbar 8 then need not be interrupted, but rather is then likewise in the form of a closed conductor loop here. In one possible configuration which is not explicitly shown, the bridge 40 is a simple conductor element, for example similar to the branch 38 of the outer busbar 10 described above in connection with FIG. 3, with the difference that the branch 38 is now routed through over the inner busbar 8 or below the latter.

In the variant shown in FIG. 5, the bridge 40 is formed by one of the connectors 6 which connects the outer busbar 10, which is on the outside of the inner busbar 8, to a contact section 42, which is on the inside of the inner busbar 8. Therefore, a contact section 42 which is connected to the cells 12 is arranged on that side of the inner busbar 8 which is opposite the outer busbar 10. In one configuration which is not shown, the contact section 42 corresponds to the connection point 22 to the cells 12 and, in the configuration shown here, the contact section 42 is a separate conductor which leads to the connection point 22 and even runs beside the inner busbar 8 and parallel to the latter in this case.

In the variant shown in FIG. 6, the bridge 40 has a diode 44 for stipulating the current direction through the cells 12, with the result that negative effects are avoided in the event of failure of the PV module 4 or shading. In principle, a configuration in which the diode 44 is part of the connector 6 in a variant according to FIG. 5 and is connected there between the outer busbar 10 and the contact section 42 is also possible and suitable.

In the embodiment according to FIG. 12, both busbars 8, 10 run transversely through the PV module and are accordingly not in the form of conductor loops. As already described, the cell array is subdivided into a plurality of cell sectors 66 which are each individually connected to the busbars via respective connection points 20, 22. The individual cell sectors 66 are then connected in parallel with one another. Nevertheless, bridging is also required in the example in FIG. 12, in this case in the center in which the busbars 8, 10 bridge one another by means of bridges which are not explicitly designated. However, it becomes clear overall that the busbars 8, 10 can be designed in a wide variety of ways in order to obtain PV modules 4 which can be used to produce a power supply system.

Returning to FIG. 4, a respective PV module 4 has two conductive layers as electrodes 16, 18. These are now encapsulated together with the active layer 14 between two barrier layers 46, that is to say the barrier layers 46 cover the electrodes 16, 18 and the active layer 14 on the top side and underside thereof. The active layer 14 and the two electrodes 16, 18 are not necessarily each individual layers, but rather are typically themselves composed of a plurality of layers. The active layer 14 has a semiconductor material for producing charge carriers which then migrate to the electrodes 16, 18 and produce a corresponding current. The entire layer structure composed of the active layer 14 and electrodes 16, 18 is encapsulated between the two barrier layers 46 in order to protect against environmental influences. These barrier layers form an outer sheath of the PV module 4. In the present case, the active layer 14 and the electrodes 16, 18 are laminated between the barrier layers 46 which are therefore also referred to as the primary laminate.

In the exemplary embodiments shown here, the two busbars 8, 10 are also arranged between the two barrier layers 46 of a respective PV module 4, with the result that the busbars are integrated in the PV module 4. In the present case, the busbars 8, 10 of a respective PV module 4 are produced together with one of the electrodes 16, 18, specifically by printing on a conductive material. One of the electrodes 16, 18, here the so-called top electrode 18, is printed on as a so-called grid electrode, wherein a conductive ink containing conductive particles, for example silver, is used as the conductive material. The busbars 8, 10 are now also printed on in the same process step as the electrode 18, that is to say they are also in the same layer as the electrode 18 in the layer structure of the PV module 4.

If the busbars 8, 10 are integrated in a respective PV module 4, the busbars 8, 10 are covered by the barrier layers 46. In order to establish contact between a connector 6 and a PV module 4, its one barrier layer 46 has, as shown in FIGS. 3, 5 and 6, a contact hole 48 through which one of the busbars 8, 10 is accessible. The contact hole 48 is cut into the barrier layer 46, for example when producing the PV module 4. Since there are two busbars 8, 10 in each PV module 4, at least two contact holes 48 are accordingly present, specifically one for each busbar 8, 10. In a variant which is not shown, a contact hole 48 extends over both busbars 8, 10 as a common contact hole 48. In order to make it possible to establish flexible contact on various sides of the PV module 4, a plurality of contact holes 48 are formed for each busbar 8, 10, as can be seen in FIGS. 3, 5 and 6, specifically here two on each side of the PV module 4. In a variant which is not shown, more than two contact holes are formed on one or more sides. In the present cases, the contact holes 48 are also arranged centrally in the edge region 26 of a respective PV module 4, wherein the two contact holes 48 for the different poles are offset relative to one another. However, such a central arrangement is not necessary and, in a variant which is not shown, the contact holes are accordingly not arranged centrally on one or more sides. Overall, the position and number of contact holes depend on the specific application.

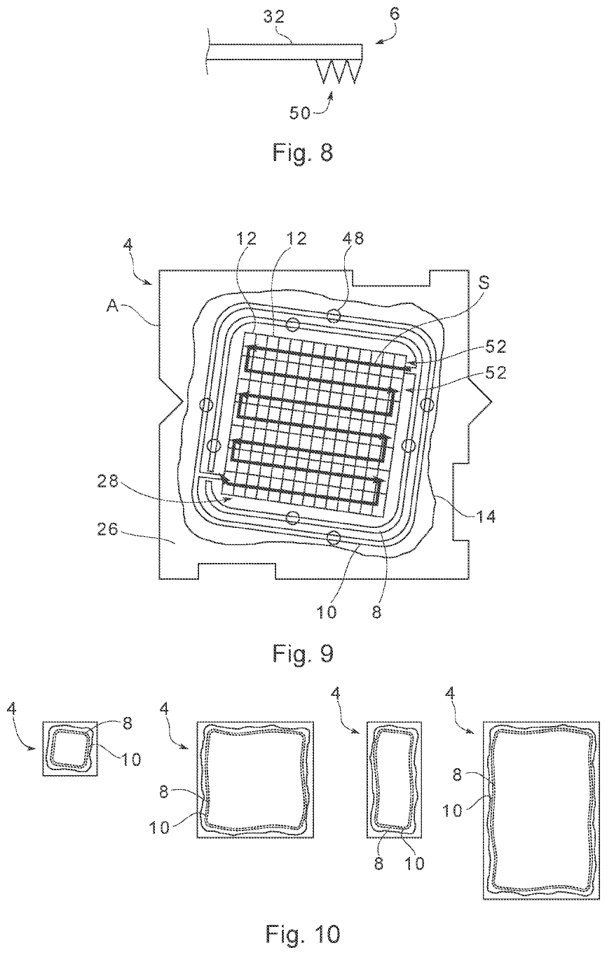

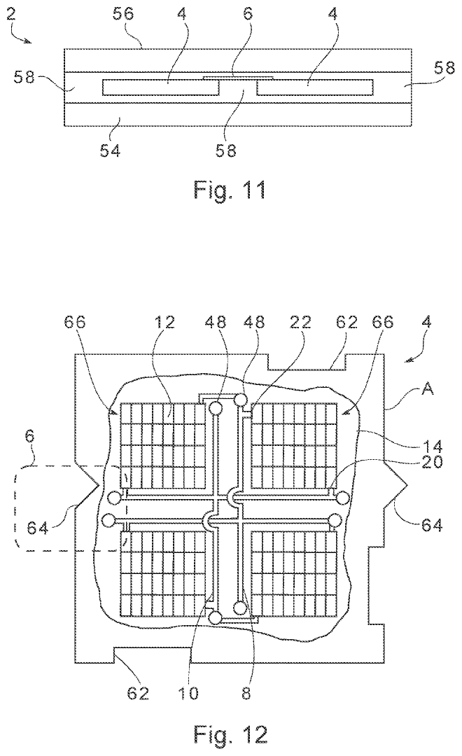

FIG. 8 shows a section of a variant of a connector 6 which, as an alternative to forming contact holes 48, is designed in such a manner that the connector 6, during connection to a PV module 4, pierces its one barrier layer 46 in the region of one of the two busbars 8, 10 in order to make contact with the latter. For this purpose, the connector 6 is in the form of a crimp, for example, and has one or more teeth 50 or mandrels which perforate the barrier layer 46 when being pressed onto the PV module 4 and then establish electrical contact with the busbar 8, 10 underneath. This configuration can fundamentally also be combined with a PV module 4 having contact holes 48.

In the present case, a respective PV module 4 has a plurality of cells 12 which are connected in series with one another, thus resulting in an accordingly high voltage. In the exemplary embodiments shown, all cells 12 of a respective PV module 4 are also connected in series with one another in such a manner that a meandering current path S is formed. An embodiment of this is shown in FIG. 9, from which it can be gathered that the cells 12 are not arranged beside one another in the form of strips, but rather in a matrix-like manner, specifically in a two-dimensional cell array. A plurality of columns 52 in which the cells are each connected in series are formed as a result. The columns 52 are then connected to one another at their ends, thus correspondingly resulting in a meandering connection in which all cells 12 are connected in series. This minimizes the dead space and increases the area which can be used to produce energy. The meandering connection can also be applied to individual cell sectors 66, as shown in FIG. 12.

The number of cells shown in the figures is merely exemplary. The number of cells 12 is typically dependent on the planned application and the required voltage. Irrespective of the number of cells 12, all cells 12 of a PV module 4 are of the same size in the present case, with the result that all cells 12 produce the same current. Depending on the dimensions of the PV module 4, the size of an individual cell 12 is possibly very small, but this is not disadvantageous since, on account of the parallel circuit of a plurality of PV modules 4, their currents are added.

As already explained, on account of the special design of the busbars 8, 10 and the resulting flexible connection, a plurality of PV modules 4 of different sizes can be combined with one another. In FIGS. 1, 2 and 7, the facade element 2 actually has a plurality of different types of PV modules 4 of different sizes. FIG. 10 shows, by way of example, four types of PV modules 4 of different sizes. The different types therefore differ in terms of their size, that is to say the physical dimensions, that is to say here specifically to the effect that they have different areas, with the result that the size of the cells 12 also accordingly differs and the PV modules 4 produce different currents. However, as described, the number of cells is the same, with the result that the different types have the same voltage and can be connected in parallel with one another without any problems. For the larger PV modules 4 in FIG. 10, a design as shown in FIG. 12 is advantageous, with the result that the individual cell sectors 66 then each correspond to one or more base units B of the grid dimension R and are equipped, for example, with cells 12 connected in series according to FIG. 9.

It can be seen, in particular in FIG. 1, but also in FIGS. 2 and 7, that in the exemplary embodiments shown here a plurality of types of PV modules 4 do not only differ in terms of their size, but also are adapted to a grid dimension R which has a particular size as a base unit B. The sizes of the various types are each integer multiples of this base unit B. The smallest PV module 4 in FIG. 10 therefore has the size of the base unit B and therefore represents, as it were, an individual pixel in the overall flat arrangement of the PV modules 4. Each PV module 4 then corresponds to one or more pixels, depending on its size. As can be seen in FIG. 2, in the configuration shown there, the connectors 6 likewise follow the grid dimension R, with the result that the connectors 6 are arranged in a manner distributed at regular intervals over the entire flat arrangement of the PV modules 4. However, this is not necessary. If appropriate, as shown, accordingly large PV modules 4 are connected several times to an accordingly large, adjacent PV module 4 via a plurality of connectors 6.

The PV modules 4 also have a polygonal design and are arranged in a tile-like manner, as becomes clear in FIG. 1, for example. In the present case, the PV modules 4 are specifically rectangular and accordingly have four corners, thus also resulting in a rectangular grid dimension R. More specifically, the grid dimension R shown here even has a square as a base unit B, with the result that the PV modules 4 are then accordingly rectangles or even squares, the respective area of which corresponds to an integer multiple of the base unit B, as shown in FIG. 10, for example. In this manner, the PV modules 4 can be arranged in an optically attractive manner in the form of a brick wall or a backsplash, as shown in FIGS. 1, 2 and 7. The parallel circuit of the PV modules 4 need not necessarily be arranged in such a grid dimension, but rather other arrangements are also possible and suitable, including those in which the PV modules 4 are spaced further apart from one another or are loosely distributed or are arranged in a freestanding manner or a combination thereof.

The optical impression of a respective PV module 4 is produced by a corresponding design of the individual elements of a respective PV module 4, with the result that a certain design also results overall for the facade element 2. In the configurations shown, the busbars 8, 10 and the active layer 14 of a respective PV module 4 are designed for this purpose in such a manner that the result is an irregular contour, here specifically a brick finish. However, the PV modules 4 need not necessarily be arranged flush with one another, as shown, but rather, in contrast, are arranged in a freestanding manner and are accordingly spaced apart from one another in one variant. The barrier layers 46 are usually transparent, but the active layer 14 and the busbars 8, 10 are not, with the result that the optical impression of an individual PV module 4 and of the facade element 2 is decisively determined overall by the shape of the busbars 8, 10 and of the active layer 14. These two elements are therefore used for design.

The facade elements 2 shown here are themselves each a laminate in which the PV modules 4 are laminated together between two layers. This is shown in FIG. 10 which shows a sectional view of a facade element 2 in order to illustrate its layer structure. The PV modules 4 are enclosed together between a front side 54 and a rear side 56 of a secondary laminate. In the present case, the front side 54 and the rear side 56 are connected to the PV modules 4 by means of an adhesive 58 and are thereby fixed and fastened to one another. Overall, the PV modules 4 are integrated in the facade element 2.

In the flat arrangement of the PV modules 4, a plurality of recesses, which the adhesive 58 can enter, are also formed between said PV modules, with the result that the adhesive extends through the area of the PV modules 4 and directly connects the front side 54 to the rear side 56. Such recesses may be implemented in various ways. The adhesive 58 also covers the PV modules 4 and the connectors 6, with the result that they are connected overall to the front side 54 and the rear side 56.

In one expedient configuration, the PV modules 4 are spaced apart from one another by joints 60 in the form of recesses in which the adhesive 58 is arranged. A configuration with joints 60 between the PV modules 4 has already been shown in FIG. 1. The joints 60 are considerably narrower than a respective PV module 4 and also considerably narrower than the grid dimension R. For the dimensions of the PV modules 4 and their adaptation to the grid dimension R and the base unit B, slight deductions or additions are made to the size, if appropriate, in order to enable additional joints 60 between adjacent PV modules 4, with the result that the size of a PV module does not necessarily correspond exactly to an integer multiple of the base unit.

As an alternative or in addition to the described joints 60, a respective PV module 4 has a contoured outer edge A, with the result that adjacent PV modules 4 abut one another only in sections and in the process form one or more recesses 62 in which an adhesive 58 connecting the front side 54 to the rear side 56 is arranged. This shall be explained, by way of example, on the basis of the PV modules 4 in FIG. 3 which have corresponding recesses 62. The outer edge A of a respective PV module 4 is generally rectangular, here even square, and is now set back in sections, with the result that additional steps or notches are formed along the outer edge A. Two PV modules 4, the outer edges A of which are placed onto one another, then abut one another, but not in the region of the steps or notches which form corresponding recesses 62 through the interaction of the two outer edges A of the adjacent PV modules 4. Such recesses 62 are produced, for example, by additionally processing the barrier layers 46 of a respective PV module 4, wherein one or more recesses 62 or cut out or stamped in. In a variant which is not explicitly shown, the recesses 62 are alternatively or additionally in the form of holes in the barrier layers 46. These holes extend completely through a respective PV module 4 and thus allow the adhesive 58 to enter.

The recesses 62 are formed only in the edge region 26 and therefore do not influence the inner region 28, the cells 12 and the active layer 14. The recesses 62 shown are rectangular or in the form of strips, but many other forms are fundamentally likewise suitable. In the present case, a PV module 4 also has a plurality of recesses 62 which are arranged on different sides of the PV module 4, with the result that the PV module 4 is surrounded or framed by adhesive 58 from a plurality of sides in the finished facade element 2.

In one possible configuration, a PV module 4 has an outer edge A which is contoured in such a manner that an orientation relative to adjacent PV modules 4 is restricted and polarity reversal protection is formed as a result. An example of this is shown in FIG. 3. Two complementary structures 64, for example a tip and an indentation on opposite sides of a respective PV module 4, are formed there on the outer edge A. An outer edge A contoured in such a manner stipulates the orientation of the PV modules 4 relative to one another.

The various concepts described above can fundamentally be used individually and in any desired combination. This relates especially but not exclusively to the concept with joins 60 and recesses 62, the interruption or bridging of the inner busbar 8, the meandering connection of cells 12 in a PV module 4 and the polarity reversal protection.

The following is a summary list of reference numerals and the corresponding structure used in the above description of the invention:
2 Facade element
4 PV module
6 Connector
8 Busbar, inner busbar
10 Busbar, outer busbar
12 Cell
14 Active layer
16 Electrode
18 Electrode
20 Connection point
22 Connection point
24 Central connection
26 Edge region
28 Inner region
30 Gap
32 Conductor (of a connector)
34 Arm
36 Feed-through
38 Branch
40 Bridge
42 Contact section
44 Diode
46 Barrier layer
48 Contact hole
50 Teeth
52 Column
54 Front side
56 Rear side
58 Adhesive
60 Join
62 Recess
64 Structure (for polarity reversal protection)
66 Cell sector
A Outer edge
B Base unit
R Grid dimension
S Current path

1. A facade element, comprising:
a plurality of connectors; and
a plurality of photovoltaic (PV) modules, said PV modules being disposed flat, with a result that each of said PV modules is adjacent to at least other one of said PV modules, each of said PV modules having cells and two busbars being connected to at least one of said cells, said busbars provided for connecting to at least one of said connectors, wherein said busbars of two adjacent ones of said PV modules being electrically connected to one another by means of a respective one of said connectors and are connected in parallel with one another, with a result that said busbars form a power supply system with said connectors.

2. The facade element according to claim 1, wherein said two busbars of a respective one of said PV modules run beside one another along an edge region of said respective PV module, with a result that one of said two busbars is an inner busbar and another of said two busbars is an outer busbar.

3. The facade element according to claim 2, wherein, in a respective one of said PV modules, at least one of said busbars is in a form of a closed conductor loop.

4. The facade element according to claim 2, wherein, in a respective one of said PV modules, said inner busbar is interrupted by said outer busbar in order to make contact with said cells.

5. The facade element according to claim 2, wherein, in a respective one of said PV modules, said outer busbar is connected to said cells by means of a bridge which bridges said inner busbar, wherein said bridge is formed by one of said connectors which connects said outer busbar, which is on an outer side of said inner busbar, to a contact section, which is on an inner side of said inner busbar.

6. The facade element according to claim 2, wherein, in a respective one of said PV modules, said outer busbar is connected to said cells by means of a bridge which bridges said inner busbar, wherein said bridge has a diode for stipulating a current direction through said cells.

7. The facade element according to claim 1, wherein a respective one of said PV modules has barrier layers, an active layer, and two conductive layers as electrodes which are encapsulated together with said active layer between said two barrier layers, and between said two barrier layers said two busbars are also disposed, with a result that they are integrated in said respective PV module.

8. The facade element according to claim 7, wherein said busbars of a respective one of said PV modules are produced together with one of said electrodes.

9. The facade element according to claim 7, wherein, in order to establish contact between one of said connectors and one of said PV modules, one said barrier layers has a contact hole formed therein and through which one of said busbars is accessible.

10. The facade element according to claim 7, wherein a respective one of said connectors is configured in such a manner that, during connection to one of said PV modules, said respective connector pierces one of said barrier layers in a region of said two busbars in order to make contact with said busbars.

11. The facade element according to claim 1, wherein all of said cells of a respective one of said PV modules are connected in series with one another in such a manner that a meandering current path is formed.

12. The facade element according to claim 1, wherein said PV modules are a plurality of different types of said PV modules of different sizes.

13. The facade element according to claim 1, wherein said PV modules each have a polygonal configuration and are disposed a tile-like manner.

14. The facade element according to claim 1, further comprising:
a secondary laminate having a front side and a rear side, said PV modules are enclosed together between said front side and said rear side of said secondary laminate; and
an adhesive, said PV modules are spaced apart from one another by joints in which said adhesive connecting said front side to said rear side is disposed.

15. The facade element according to claim 1, further comprising:
a secondary laminate having a front side and a rear side, said PV modules are enclosed together between said front side and said rear side of said secondary laminate; and
an adhesive, a respective one of said PV modules has a contoured outer edge, with a result that adjacent ones of said PV modules abut one another only in sections and in a process define at least one recess in which said adhesive connecting said front side to said rear side is disposed.

16. The facade element according to claim 1, wherein a respective one of said PV modules has an outer edge which is contoured in such a manner that an orientation relative to adjacent ones of said PV modules is restricted and polarity reversal protection is formed as a result.

17. The facade element according to claim 1, wherein said PV modules are organic PV modules.

18. The facade element according to claim 7, wherein said busbars of a respective one of said PV modules are produced together with one of said electrodes by printing on a conductive material.

19. A photovoltaic (PV) module for a facade element according to claim 1.
